(19) United States
(12) Patent Application Publication
(10) Pub. No.: US 2026/0074144 A1
(43) Pub. Date: Mar. 12, 2026

(54) RASTER BEAM WRITING METHOD AND RASTER BEAM WRITING APPARATUS

(71) Applicant: NuFlare Technology, Inc., Yokohama-shi (JP)

(72) Inventors: Hiroshi MATSUMOTO, Yokohama-shi (JP); Yuji FUJIWARA, Yokohama-shi (JP)

(73) Assignee: NuFlare Technology, Inc., Yokohama-shi (JP)

(21) Appl. No.: 19/294,507

(22) Filed: Aug. 8, 2025

(30) Foreign Application Priority Data
Sep. 9, 2024 (JP) 2024-155060

(51) Int. Cl. H01J 37/304; H01J 37/317

(52) U.S. Cl. CPC H01J 37/304; H01J 37/3174; H01J 2237/30488; H01J 2237/31769

(57) ABSTRACT

A raster beam writing method includes: calculating a ghost dose for ghost exposure for a small region having a proximity effect-corrected dose larger than the threshold value as a result of a determination; and for a plurality of irradiation unit regions to be irradiated with a charged particle beam obtained by dividing the writing region of the target object in a mesh shape, writing an irradiation unit region having a proximity effect-corrected dose larger than the threshold value with a charged particle beam having an incident dose obtained by adding the ghost dose to a dose based on a limited corrected dose more limited than a calculated proximity effect-corrected dose, and writing an irradiation unit region having a proximity effect-corrected dose not larger than the threshold value with a charged particle beam having an incident dose based on the calculated proximity effect-corrected dose without ghost exposure.

### CROSS-REFERENCE TO RELATED APPLICATION

This application is based upon and claims the benefit of priority from prior Japanese Patent Application No. 2024-155060 filed on Sep. 9, 2024 in Japan, the entire contents of which are incorporated herein by reference.

### BACKGROUND OF THE INVENTION

### Field of the Invention

One aspect of the present invention relates to a raster beam writing (or “drawing”) method and a raster beam writing apparatus, for example, a raster writing type single/multi-beam writing apparatus and a method thereof.

### Related Art

Lithography technology, which is responsible for the progress of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam lithography technology is basically excellent in terms of resolution, and writing is performed on a mask for wafer exposure, a wafer, and the like using an electron beam.

For example, there is a writing apparatus using multiple electron beams. Compared to the case of writing using a single electron beam, using multiple electron beams allows irradiation using a large amount of beams at a time, resulting in a significant improvement in throughput. In such a multi-beam type writing apparatus, for example, an electron beam emitted from an electron emission source passes through a mask having a plurality of holes to form multiple beams, and each of the multiple beams is subjected to blanking control so that each beam that is not blocked is demagnified by an optical system, deflected by a deflector, and emitted to a desired position on a target object.

Here, in raster beam writing using a single electron beam or multiple electron beams, the shot cycle and the writing speed are usually determined according to the maximum dose within a writing region or a writing stripe. The larger the maximum dose, the slower the writing speed, and as a result, the longer the writing time. In the case of writing using an electron beam, when a resist-coated target object is irradiated with the beam, the beam is back scattered within the target object to cause electrons to be incident on the resist, thereby causing secondary resist exposure. As a result, a so-called proximity effect occurs in which the secondary exposure is stronger in a region with a higher pattern area density. When proximity effect correction is performed by dose modulation, the dose is modulated so that the lower the pattern area density, the larger the dose. The mask has a main pattern region where a pattern to be transferred onto a wafer by a scanner is arranged and a peripheral pattern region outside the main pattern region where a pattern for mask management is arranged. High writing accuracy is required for the main pattern region, but such high writing accuracy is often not required for the peripheral pattern region. When the density of the peripheral pattern region is lower than that of the main pattern region, the maximum dose in the former is larger than that in the latter. Therefore, when attempting to write the main pattern region and the peripheral pattern region at the same time in order to shorten the writing time, an unreasonable situation may occur in which the writing speed in the main chip is reduced due to the maximum dose of the peripheral chip with low writing accuracy requirements.

Therefore, by limiting the dose exceeding the range of the dose used in the main chip region, which requires high writing accuracy, in the entire region including the main chip region and the peripheral chip region, the maximum dose in the entire region can be reduced. This makes it possible to shorten the writing time without affecting the pattern writing accuracy in the main chip region. In such a case, however, there has been a problem that the dose is insufficient in the peripheral chip region where the dose is limited and accordingly, the pattern size is reduced.

Here, a technique is disclosed in which, in addition to irradiating a position where a pattern is located (line pattern portion) with a beam having a dose that resolves a resist at a desired pattern width, a portion where there is no pattern (space portion) is also irradiated with a beam having a dose that does not resolve the pattern, thereby being able to reduce the dose at the position where the pattern is located and accordingly shortening the writing time (see Published Unexamined Japanese Patent Application No. 2015-005729).

### BRIEF SUMMARY OF THE INVENTION

According to one aspect of the present invention, a raster beam writing method, includes:
calculating a normalized proximity effect-corrected dose for correcting a proximity effect in a case of writing a target object with a charged particle beam;
determining, for each of a plurality of small regions obtained by dividing a writing region of the target object in a mesh shape, whether or not a proximity effect-corrected dose of a small region is larger than a threshold value;
calculating a ghost dose for ghost exposure for a small region having a proximity effect-corrected dose larger than the threshold value as a result of the determination; and
for a plurality of irradiation unit regions to be irradiated with a charged particle beam obtained by dividing the writing region of the target object in a mesh shape, writing an irradiation unit region having a proximity effect-corrected dose larger than the threshold value with a charged particle beam having an incident dose obtained by adding the ghost dose to a dose based on a limited corrected dose more limited than a calculated proximity effect-corrected dose, and writing an irradiation unit region having a proximity effect-corrected dose not larger than the threshold value with a charged particle beam having an incident dose based on the calculated proximity effect-corrected dose without ghost exposure.

According to another aspect of the present invention, a raster beam writing apparatus, includes:
a proximity effect-corrected dose calculation circuit configured to calculate a normalized proximity effect-corrected dose for correcting a proximity effect in a case of writing a target object with a charged particle beam;
a determination circuit configured to determine, for each of a plurality of small regions obtained by dividing a writing region of the target object in a mesh shape, whether or not a proximity effect-corrected dose of a small region is larger than a threshold value;
a ghost dose calculation circuit configured to calculate a ghost dose for ghost exposure for a small region having a proximity effect-corrected dose larger than the threshold value as a result of the determination; and
a writing mechanism configured, for a plurality of irradiation unit regions to be irradiated with a charged particle beam obtained by dividing the writing region of the target object in a mesh shape, to write an irradiation unit region having a proximity effect-corrected dose larger than the threshold value with a charged particle beam having an incident dose obtained by adding the ghost dose to a dose based on a limited corrected dose more limited than the calculated proximity effect-corrected dose and write an irradiation unit region having a proximity effect-corrected dose not larger than the threshold value with a charged particle beam having an incident dose based on the calculated proximity effect-corrected dose without ghost exposure.

### BRIEF DESCRIPTION OF THE DRAWINGS

FIG. 1 is a conceptual diagram showing the configuration of a writing apparatus according to Embodiment 1;

FIG. 2 is a conceptual diagram showing the configuration of a shaping aperture array substrate in Embodiment 1;

FIG. 3 is a cross-sectional view showing the configuration of a blanking aperture array mechanism in Embodiment 1; 30

FIG. 4 is a conceptual diagram for explaining an example of a writing operation in Embodiment 1;

FIG. 5 is a diagram showing an example of a region irradiated with multiple beams and a writing target pixel in Embodiment 1;

FIG. 6 is a diagram showing an example of the arrangement of a pattern region to be written in Embodiment 1;

FIG. 7 is a diagram showing an example of the relationship between the proximity effect density and the dose incident on a resist on a target object surface in a comparative example of Embodiment 1;

FIG. 8 is a flowchart showing an example of main steps of a writing method according to Embodiment 1;

FIG. 9 is a diagram showing an example of the relationship between the proximity effect-corrected dose and the proximity effect density in Embodiment 1;

FIG. 10 is a diagram showing an example of the relationship between the proximity effect density and the dose in Embodiment 1;

FIG. 11 is a diagram showing an example of the relationship between the dose and the proximity effect density in Embodiment 1;

FIG. 12 is a diagram for explaining an example of a multi-beam writing operation in Embodiment 1;

FIG. 13 is a conceptual diagram showing the configuration of a writing apparatus according to Embodiment 2;

FIG. 14 is a flowchart showing an example of main steps of a writing method according to Embodiment 2; and

FIG. 15 is a diagram showing an example of the relationship between the pattern size and the dose in Embodiment 2.

### DETAILED DESCRIPTION OF THE INVENTION

In the following embodiments, a writing method and a writing apparatus are provided that can shorten the writing time while maintaining the pattern size even in a peripheral chip region, without affecting the pattern writing accuracy in the main chip region, in raster beam writing.

In addition, in the following embodiments, a configuration using an electron beam as an example of a charged particle beam will be described. However, the charged particle beam is not limited to an electron beam, and may be a beam using a charged particle such as an ion beam. The charged particle beam may be a single beam or multiple beams. In the following embodiments, for example, a multi-beam writing apparatus that performs raster beam writing will be described. In addition, for example, this may be a single-beam writing apparatus that performs raster beam writing.

### Embodiment 1

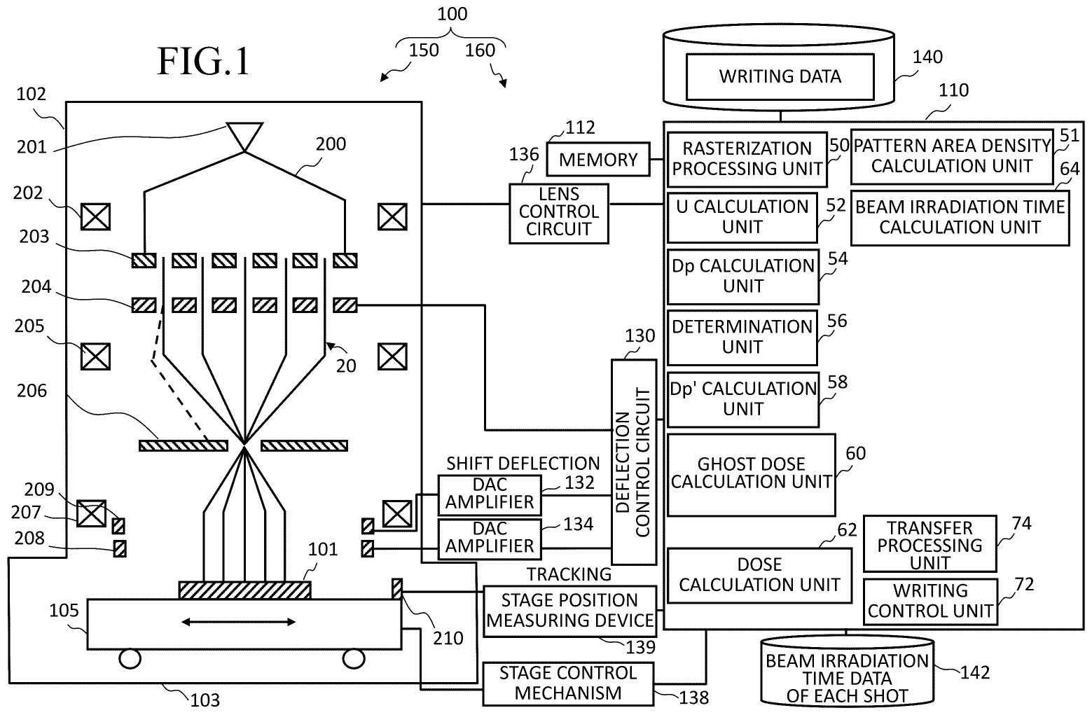

FIG. 1 is a conceptual diagram showing the configuration of a writing apparatus according to Embodiment 1. In FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. In addition, the writing apparatus 100 is an example of a raster beam writing apparatus. The writing mechanism 150 includes an electron optical column 102 (electron beam column) and a writing chamber 103. In the electron optical column 102, an electron emission source 201, an illumination lens 202, a shaping aperture array substrate 203, a blanking aperture array mechanism 204, a demagnifying lens 205, a limiting aperture substrate 206, an objective lens 207, a main deflector 208, and a sub-deflector 209 are arranged.

An XY stage 105 is arranged in the writing chamber 103. On the XY stage 105, a target object 101 such as a mask, which becomes a writing target substrate during writing (during exposure), is arranged. The target object 101 includes an exposure mask used in manufacturing a semiconductor device, a semiconductor substrate (silicon wafer) on which a semiconductor device is manufactured, and the like. In addition, the target object 101 includes a mask blank which is coated with resist and on which nothing has been written yet. A mirror 210 for measuring the position of the XY stage 105 is further arranged on the XY stage 105.

The control system circuit 160 includes a control calculator 110, a memory 112, a deflection control circuit 130, digital-to-analog conversion (DAC) amplifier units 132 and 134, a lens control circuit 136, a stage control mechanism 138, a stage position measuring device 139, and storage devices 140 and 142 such as magnetic disk drives. The control calculator 110, the memory 112, the deflection control circuit 130, the lens control circuit 136, the stage control mechanism 138, the stage position measuring device 139, and the storage devices 140 and 142 are connected to each other through a bus (not shown). The DAC amplifier units 132 and 134 and the blanking aperture array mechanism 204 are connected to the deflection control circuit 130. The sub-deflector 209 is configured by electrodes having four or more poles, and each electrode is controlled by the deflection control circuit 130 through the DAC amplifier 132. The main deflector 208 is configured by electrodes having four or more poles, and each electrode is controlled by the deflection control circuit 130 through the DAC amplifier 134. A group of lenses such as the illumination lens 202, the demagnifying lens 205, and the objective lens 207 are controlled by the lens control circuit 136.

The position of the XY stage 105 is controlled by driving motors for each axis (not shown) controlled by the stage control mechanism 138. The stage position measuring device 139 measures the position of the XY stage 105 using the principle of laser interferometry by receiving the reflected light from the mirror 210.

In the control calculator 110, a rasterization processing unit 50, a pattern area density calculation unit 51, a proximity effect density calculation unit (U calculation unit) 52, a proximity effect-corrected dose calculation unit (Dp calculation unit) 54, a determination unit 56, a limited corrected dose calculation unit (Dp′ calculation unit) 58, a ghost dose calculation unit 60, a dose calculation unit 62, a beam irradiation time calculation unit 64, a writing control unit 72, and a transfer processing unit 74 are arranged. Each “˜ unit”, such as the rasterization processing unit 50, the pattern area density calculation unit 51, the proximity effect density calculation unit 52, the proximity effect-corrected dose calculation unit 54, the determination unit 56, the limited corrected dose calculation unit 58, the ghost dose calculation unit 60, the dose calculation unit 62, the beam irradiation time calculation unit 64, the writing control unit 72, and the transfer processing unit 74, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input to and output from the rasterization processing unit 50, the pattern area density calculation unit 51, the proximity effect density calculation unit 52, the proximity effect-corrected dose calculation unit 54, the determination unit 56, the limited corrected dose calculation unit 58, the ghost dose calculation unit 60, the dose calculation unit 62, the beam irradiation time calculation unit 64, the writing control unit 72, and the transfer processing unit 74 and information being calculated are stored in the memory 112 each time.

The writing operation of the writing apparatus 100 is controlled by the writing control unit 72. In addition, processing for the transfer of beam irradiation time data of each shot to the deflection control circuit 130 is controlled by the transfer processing unit 74.

In addition, writing data (chip data) is input from outside the writing apparatus 100 and is stored in the storage device 140. The chip data defines information of a plurality of figure patterns forming a chip pattern. Specifically, for each figure pattern, the coordinates of each vertex are defined in an order that forms the figure. Alternatively, for example, a figure code, coordinates, size, and the like are defined for each figure pattern.

Here, FIG. 1 describes components necessary for explaining Embodiment 1. The writing apparatus 100 may also include other components that are normally required.

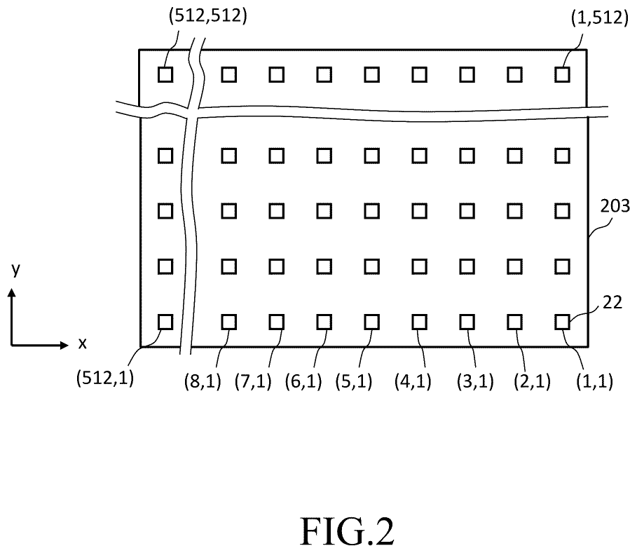

FIG. 2 is a conceptual diagram showing the configuration of a shaping aperture array substrate according to Embodiment 1. In FIG. 2, in the shaping aperture array substrate 203, holes (openings) 22 are formed in a matrix of p rows long (in the x direction) and q columns wide (in the y direction) (p, q≥2) at arrangement pitches. In the example of FIG. 2, a case is shown in which, for example, a 512×512 array of holes 22 are formed in length and width directions (x and y directions). The number of holes 22 is not limited to this. For example, a 32×32 array of holes 22 may be formed. The holes 22 are formed in rectangles having the same size and shape. Alternatively, the holes 22 may be circles having the same diameter. Some of electron beams 200 pass through the plurality of holes 22 to form multiple beams 20. In other words, the shaping aperture array substrate 203 forms and emits the multiple beams 20. The shaping aperture array substrate 203 is an example of an emission source of the multiple beams 20 or a multiple beam forming mechanism.

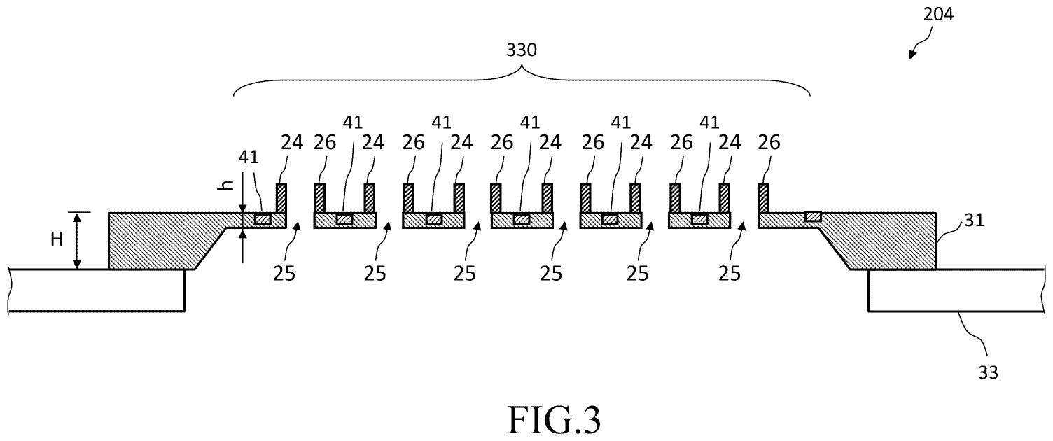

FIG. 3 is a cross-sectional view showing the configuration of a blanking aperture array mechanism in Embodiment 1. In the blanking aperture array mechanism 204, as shown in FIG. 3, a blanking aperture array substrate 31 using a semiconductor substrate formed of silicon or the like is arranged on a support base 33. In a membrane region 330 in a central portion of the blanking aperture array substrate 31, a passage hole 25 (opening) through which each of the multiple beams 20 passes is opened at a position corresponding to each hole 22 of the shaping aperture array substrate 203 shown in FIG. 2. Then, a set of a control electrode 24 and a counter electrode 26 (blanker: blanking deflector) are arranged at positions facing each other with a corresponding passage hole 25 among the plurality of passage holes 25 interposed therebetween. In addition, a control circuit 41 (logic circuit) to apply a deflection voltage to the control electrode 24 for each passage hole 25 is arranged inside the blanking aperture array substrate 31 near each passage hole 25. The counter electrode 26 for each beam is grounded.

In the control circuit 41, an amplifier (an example of a switching circuit), which is not shown, is arranged. As an example of the amplifier, a CMOS (Complementary MOS) inverter circuit serving as a switching circuit is arranged. Either an L (low) potential (for example, ground potential) that is lower than the threshold voltage or an H (high) potential (for example, 1.5 V) that is equal to or higher than the threshold voltage is applied to the input (IN) of the CMOS inverter circuit as a control signal. In Embodiment 1, in a state in which the L potential is applied to the input (IN) of the CMOS inverter circuit, the output (OUT) of the CMOS inverter circuit, which is the output of the control circuit 41, has a positive potential (Vdd), and the corresponding beam is deflected by the electric field due to the potential difference from the ground potential of the counter electrode 26 and shielded by the limiting aperture substrate 206. In this manner, the beam is controlled to be turned off. On the other hand, in a state in which the H potential is applied to the input (IN) of the CMOS inverter circuit (active state), the output (OUT) of the CMOS inverter circuit and the control circuit 41 has a ground potential, and there is no potential difference from the ground potential of the counter electrode 26. Therefore, since the corresponding beam is not deflected, the beam passes through the limiting aperture substrate 206. In this manner, the beam is controlled to be turned on. Blanking is controlled by such deflection.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple beams 20 pass through corresponding blankers of the blanking aperture array mechanism 204. Each of the blankers performs blanking control on a beam passing therethrough so that the beam is in an ON state for a set writing time (beam irradiation time).

The multiple beams 20 that have passed through the blanking aperture array mechanism 204 are reduced by the demagnifying lens 205 and travel toward a central hole formed in the limiting aperture substrate 206. Here, the electron beam deflected by the blanker of the blanking aperture array mechanism 204 is displaced from the central hole of the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. Thus, the limiting aperture substrate 206 blocks each beam that is deflected by the blanker of the blanking aperture array mechanism 204 so as to be in a beam OFF state. Then, by the beam that has passed through the limiting aperture substrate 206 and is formed from the beam ON state to the beam OFF state, each beam of one shot is formed. The multiple beams 20 that have passed through the limiting aperture substrate 206 are focused by the objective lens 207 to become a pattern image having a desired reduction ratio, and all of the multiple beams 20 that have passed through the limiting aperture substrate 206 are collectively deflected in the same direction by the main deflector 208 and the sub-deflector 209 and emitted to each irradiation position on the target object 101 of each beam. In addition, for example, when the XY stage 105 is continuously moving, tracking control is performed by the main deflector 208 so that the irradiation position of the beam follows the movement of the XY stage 105. The multiple beams 20 emitted at one time are ideally arranged at a pitch obtained by multiplying the arrangement pitch of the plurality of holes 22 of the shaping aperture array substrate 203 by the desired reduction ratio described above.

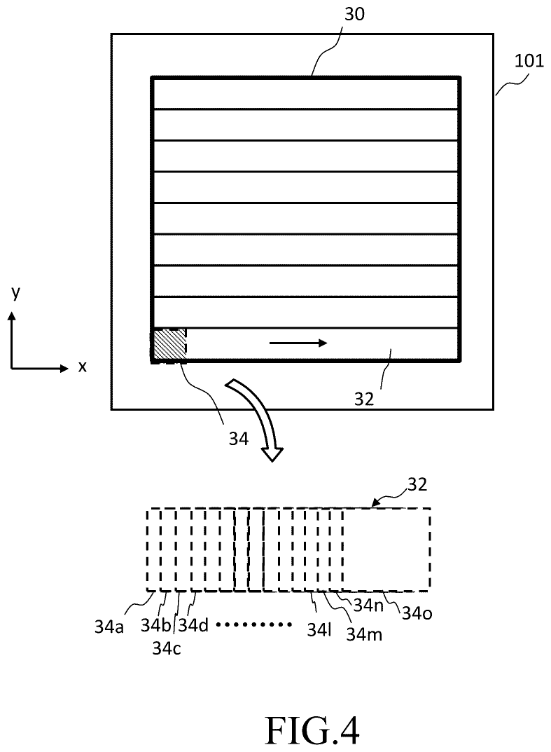

FIG. 4 is a conceptual diagram for explaining an example of the writing operation in Embodiment 1. As shown in FIG. 4, a writing region 30 (bold line) of the target object 101 is divided into a plurality of rectangular striped regions 32 having a predetermined width in the y direction, for example. In the example of FIG. 4, a case is shown in which the writing region 30 of the target object 101 is divided into a plurality of striped regions 32, for example, in the y direction, with the substantially the same width as the designed size of the irradiation region 34 (writing field) that can be irradiated with one-time multiple beams 20. The designed size of the irradiation region 34 of the multiple beams 20 in the x direction can be defined as the number of beams in the x direction x the pitch between beams in the x direction. The size of the rectangular irradiation region 34 in the y direction can be defined as the number of beams in the y direction x the pitch between beams in the y direction.

First, the XY stage 105 is moved to make an adjustment so that the irradiation region 34 of the multiple beams 20 is located at the left end of the first striped region 32 or further to the left, and writing in the first striped region 32 is performed. When writing the first striped region 32, the XY stage 105 is moved, for example, in the −x direction, so that the writing proceeds relatively in the x direction. The XY stage 105 is continuously moved, for example, at a constant speed. At this time, the speed of the XY stage 105 is determined according to the maximum dose in the striped region 32 or the writing region 30. After the writing in the first striped region 32 ends, the stage position is moved in the −y direction by the width of the striped region 32.

Then, an adjustment is made so that the irradiation region 34 of the multiple beams 20 is located at the left end of the second striped region 32 or further to the left, and the XY stage 105 is moved, for example, in the −x direction so that the writing proceeds relatively in the x direction. In this manner, the writing in the second striped region 32 is performed.

In addition, although the case where the writing in each striped region 32 proceeds in the same direction is shown in the example of FIG. 4, the invention is not limited thereto. For example, for the striped region 32 to be written next to the striped region 32 where writing has proceeded in the x direction, the writing may be performed in the −x direction by moving the XY stage 105, for example, in the x direction. By performing writing while alternately changing the direction in this manner, the stage movement time can be shortened, and the writing time can be shortened. In one shot, by the multiple beams formed by passing through each hole 22 of the shaping aperture array substrate 203, a plurality of shot patterns, up to the same number as each hole 22, are formed at a time.

In addition, although the case where the stage movement for writing in each striped region is performed once at a time is shown in the example of FIG. 4, the invention is not limited thereto. It is also preferable to perform multi-writing (multi-pass writing) by moving the stage multiple times on the same position. In this case, for example, it is preferable to perform multi-writing while shifting in the y direction by a shift amount of 1/n of the width of the striped region. Alternatively, it is also preferable to perform multi-writing (multi-writing within a pass) in which the same position is written multiple times with different beams during one stage movement.

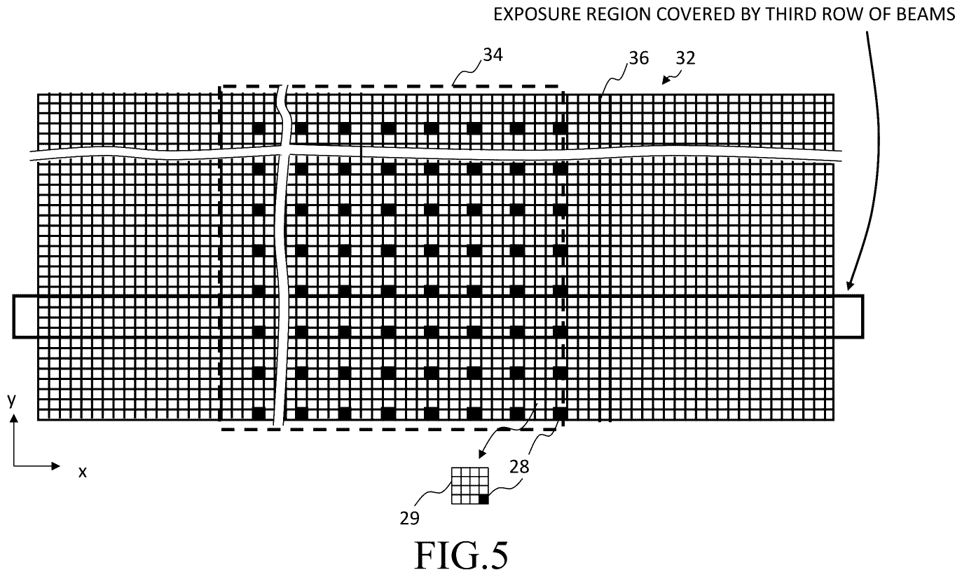

FIG. 5 is a diagram showing an example of a region irradiated with multiple beams and a writing target pixel in Embodiment 1. In FIG. 5, the striped region 32 is divided into a plurality of mesh regions with the beam size of the multiple beams 20, for example. Each of such mesh regions is a writing target pixel 36 (beam irradiation unit region, irradiation position). The size of the writing target pixel 36 is not limited to the beam size, and may be any size regardless of the beam size. For example, the size of the writing target pixel 36 may be 1/n (n is an integer of 1 or more) of the beam size. In the example of FIG. 5, a case is shown in which the writing region of the target object 101 is divided into a plurality of striped regions 32, for example, in the y direction, with the substantially the same width as the size of the irradiation region 34 (writing field) that can be irradiated with one-time multiple beams 20. The size of the rectangular irradiation region 34 in the x direction can be defined as the number of beams in the x direction x the pitch between beams in the x direction. The size of the rectangular irradiation region 34 in the y direction can be defined as the number of beams in the y direction x the pitch between beams in the y direction. In the example of FIG. 5, for example, a 512×512 array of multiple beams is abbreviated to an 8×8 array of multiple beams. Then, in the irradiation region 34, a plurality of pixels 28 (beam writing positions) that can be irradiated with one shot of the multiple beams 20 are shown. The pitch between the pixels 28 adjacent to each other is the pitch between the multiple beams. A rectangular region surrounded with the size of the inter-beam pitch in the x and y directions is one sub-irradiation region 29 (pitch cell region). In the example of FIG. 5, a case is shown in which each sub-irradiation region 29 is formed by, for example, 4×4 pixels.

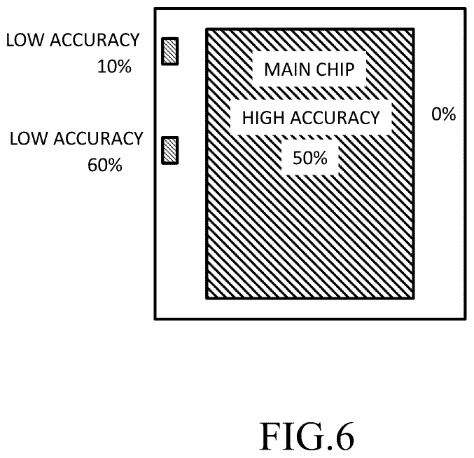

FIG. 6 is a diagram showing an example of the arrangement of a pattern region to be written in Embodiment 1. In the example of FIG. 6, a case is shown in which a mask for wafer exposure is used as the target object 101. In this case, the writing region of the target object 101 includes a main writing region located in the central portion of the target object and a sub-writing region located around the main writing region. As shown in FIG. 6, in the central portion of the target object 101, there are a main pattern region where a pattern to be transferred onto a wafer by a scanner is arranged and a peripheral pattern region outside the main pattern region where a pattern for mask management is arranged. Patterns are stored as writing data in units called chips. High writing accuracy is required for the main pattern region or the patterns included in the main chip, but high writing accuracy is often not required for the peripheral pattern region or the patterns included in the peripheral chip. If the main chip and peripheral chip are exposed separately, the number of times the XY stage 105 turns around increases. Therefore, it is preferable to set a writing stripe so as to include both the main chip and the peripheral chip and write the main chip and the peripheral chip together, since this can minimize the number of times the XY stage 105 turns around and the time required. The main pattern region (main chip region) corresponds to the main writing region. The peripheral pattern region (peripheral chip region) corresponds to the sub-writing region.

As described above, in raster beam writing, the writing speed is usually determined according to the maximum dose with which the pixel 36 is irradiated once. The larger the maximum dose, the slower the writing speed, and as a result, the longer the writing time. In addition, when performing proximity effect correction, the dose increases as the pattern area density decreases. There are chips in which the peripheral patterns, such as alignment marks, have a low density and are permissible even if the writing accuracy is low. In the example of FIG. 6, a case is shown in which the pattern area density of the figure patterns arranged in the main chip is, for example, 50% or more. In addition, one of the two peripheral chips has a pattern area density of, for example, 108. The other of the two peripheral chips has a pattern area density of, for example, 60%.

Here, by limiting the dose exceeding the range of the dose used in the main chip region, which requires high writing accuracy, in the entire region including the main chip region and the peripheral chip region, the maximum dose in the entire region can be reduced. Therefore, it is possible to shorten the writing time without affecting the pattern writing accuracy in the main chip. In such a case, however, there has been a problem that the dose is insufficient in the peripheral chip region where the dose is limited and accordingly, the pattern size is reduced.

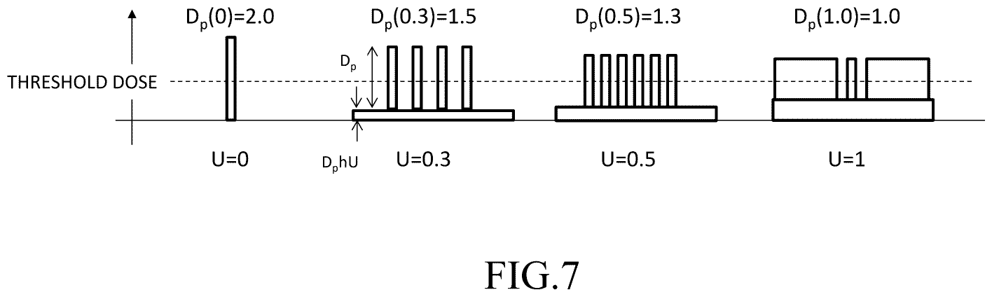

FIG. 7 is a diagram showing an example of the relationship between the proximity effect density and the dose incident on the resist on the surface of the target object 101 in a comparative example to Embodiment 1. In the example of FIG. 7, a proximity effect-corrected dose Dp when the base exposure density of the beam (base dose) is normalized as 1 is shown as a dose by beam irradiation. In addition, in the example of FIG. 7, an example of the dose required to obtain a uniform pattern size by correcting the proximity effect when a proximity effect density U is, for example, 0, 0.3, 0.5, and 1 is shown. In electron beam writing, the beam dose is set so that the dose at a position where the height of the dose distribution applied to the resist by beam irradiation is ½ matches the development threshold for developing the resist on the surface of the target object 101. When the proximity effect density U, which is an average density in the range of influence of the proximity effect and, is not 0, that is, when the proximity effect exists, there is a dose due to back scattering, and in a region where the proximity effect density is uniformly U, the dose due to back scattering is DpηU using a back scattering coefficient η. In order to determine the beam dose for which the proximity effect correction is performed appropriately, the dose DpηU due to back scattering is used as a base, and the dose twice a dose from this base to the development threshold is set as the beam dose.

The dose due to back scattering changes in value according to the proximity effect density U. The larger the proximity effect density U, the larger the base back scattering dose. The resolution threshold (threshold dose in FIG. 7) is determined by the mask process and is a value independent of the proximity effect density U. Therefore, the larger U, the larger the back scattering dose, so that the dose should be reduced accordingly (in order to maintain the pattern size, the incident dose should be reduced). Conversely, if the proximity effect density U is small, the incident dose should be increased accordingly (in order to maintain the pattern size, the incident dose should be increased). The incident dose is adjusted by a proximity effect correction coefficient Dp. When U=1, for example, Dp=1.0. When U=0.5, for example, Dp=1.3. When U=0.3, for example, Dp=1.5. When U=0, for example, Dp=2.0.

In the peripheral chip region, the proximity effect density U may be smaller than that in the main chip region. In such a case, a large incident dose, which is unnecessary in the main chip region where high writing accuracy is required, becomes necessary in the peripheral chip region where low writing accuracy is acceptable. As a result, the writing speed in the peripheral chip region is reduced to increase the writing time.

Therefore, in Embodiment 1, the dose exceeding the range (maximum value) of the incident dose used in the main chip region is limited in the entire region including the main chip region and the peripheral chip region, and ghost exposure is performed to accumulate a dose that does not resolve the resist in order to compensate for the insufficient incident dose in the peripheral chip region. Hereinafter, a specific description will be given.

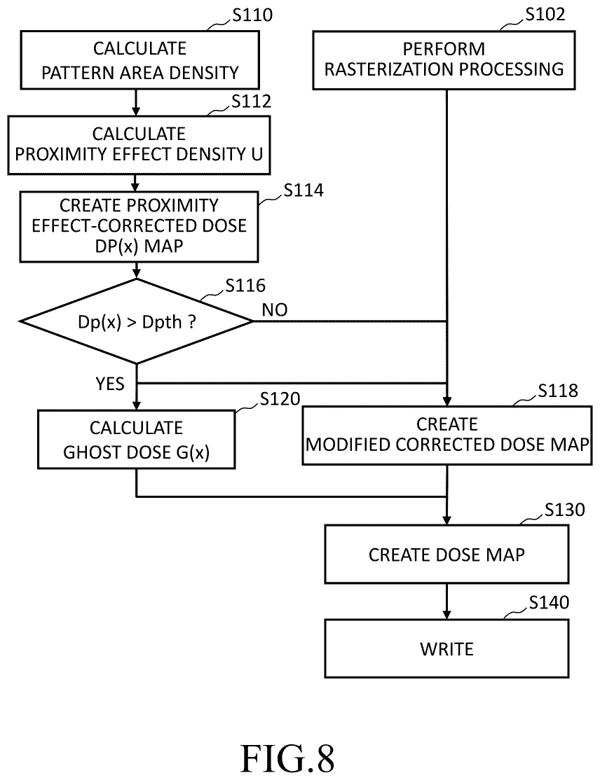

FIG. 8 is a flowchart showing an example of main steps of a writing method according to Embodiment 1. In FIG. 8, in the writing method according to Embodiment 1, a series of steps including a rasterization processing step (S102), a pattern area density calculation step (S110), a proximity effect density calculation step (S112), a proximity effect-corrected dose map creation step (S114), a determination step (S116), a modified corrected dose map creation step (S118), a ghost dose calculation step (S120), a dose map creation step (S130), and a writing step (S140) are executed.

In the rasterization processing step (S102), the rasterization processing unit 50 reads out chip pattern data (writing data) from the storage device 140 and performs rasterization processing. Specifically, for each pixel 36, the pattern area density ρ(x) of the figure pattern(s) arranged in the pixel is calculated. For example, it is preferable to perform the rasterization processing for each striped region 32.

In the pattern area density calculation step (S110), the pattern area density calculation unit 51 calculates, for each of a plurality of proximity mesh regions (small regions) that are larger in size than the pixel 36 and are obtained by dividing the striped region 32 in a mesh shape, the pattern area density ρ″ of the figure pattern(s) arranged in the proximity mesh region. In other words, the proximity mesh region is set with a mesh size smaller than a plurality of pixels 36 obtained by dividing the striped region 32 in a mesh shape. The pattern area density ρ″ is calculated for each proximity mesh region having such a small mesh size. It is preferable to set the size of the proximity mesh region in length and width directions to about 1/10 of the influence radius of the proximity effect. For example, it is preferable to set the size of the proximity mesh region in length and width directions to about 1 μm. In addition, for example, it is preferable to calculate, for each striped region 32, the pattern area density ρ″ of a plurality of proximity mesh regions in the striped region 32.

In the proximity effect density calculation step (S112), the proximity effect density calculation unit 52 calculates the proximity effect density U by using a pattern area density ρ″ (x) and a distribution function g(x). The proximity effect density U can be defined by the following Equation (1), which performs a convolution between the pattern area density ρ″ (x) and the distribution function g(x). As the distribution function g(x), it is preferable to use a Gaussian function having a width of, for example, 10 μm, which serves as a kernel representing the dose distribution applied to the resist by back scattering. Hereinafter, for ease of understanding, the coordinates (x, y) of each position in each equation are represented as x.

$$U = \int {ρ}^{″} ( {x}^{′} ) g ( x - {x}^{′} ) {dx}^{′} \qquad ( 1 )$$

In the proximity effect-corrected dose map creation step (S114), the proximity effect-corrected dose calculation unit 54 calculates a normalized proximity effect-corrected dose Dp(x) for correcting the proximity effect when writing the target object 101 with an electron beam. In other words, the proximity effect-corrected dose calculation unit 54 calculates the proximity effect-corrected dose Dp(x) for correcting the proximity effect for each proximity mesh region (small region). The unknown proximity effect-corrected dose Dp(x) can be defined by a threshold model for proximity effect correction similar to that in the conventional method, using the back scattering coefficient η and the proximity effect density U (x). The proximity effect-corrected dose Dp(x) is calculated as a relative value normalized with the base exposure density of the beam Dbase being 1. The proximity effect-corrected dose Dp(x) can be defined, for example, by the following Equation (2).

$$Dp ( x ) = ( 1 / 2 + η ) / ( 1 / 2 + η U ( x ) ) \qquad ( 2 )$$

The proximity effect-corrected dose calculation unit 54 creates a proximity effect-corrected dose map (first proximity effect-corrected dose map) having the calculated proximity effect-corrected dose Dp(x) for each proximity mesh region as an element.

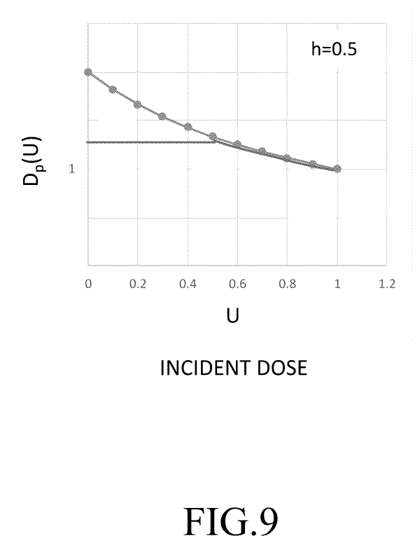

FIG. 9 is a diagram showing an example of the relationship between the proximity effect-corrected dose and the proximity effect density in Embodiment 1. In FIG. 9, the vertical axis indicates the proximity effect-corrected dose Dp. The horizontal axis indicates the proximity effect density U. As shown in FIG. 9, the proximity effect-corrected dose Dp depends on the proximity effect density U, and increases as the proximity effect density U decreases. When the minimum value of the proximity effect density U of the figure pattern in the main chip region is, for example, U=0.5, assuming that the proximity effect-corrected dose Dp at this time is a threshold value, Dp exceeding the threshold value is limited.

In the determination step (S116), the determination unit 56 determines, for each of a plurality of proximity mesh regions (an example of a small region) obtained by dividing the target striped region 32 (an example of a writing region) of the target object 101 in a mesh shape, whether or not the proximity effect-corrected dose Dp(x) of the proximity mesh region is larger than a threshold value Dpth. Alternatively, the determination unit 56 may determine, for each of a plurality of pixels 36 (another example of a small region) obtained by dividing the target striped region 32 (an example of a writing region) of the target object 101 in a mesh shape, whether or not the proximity effect-corrected dose Dp(x) of the pixel 36 is larger than the threshold value Dpth.

As the threshold value Dpth, a value equal to or greater than the proximity effect-corrected dose used in the main chip region written on the target object 101 is used. For example, the proximity effect-corrected dose Dp(x) corresponding to the minimum value of the proximity effect density U of the figure pattern in the main chip region is set as the threshold value Dpth. For example, the proximity effect-corrected dose Dp(x) when U=0.5 is set as the threshold value Dpth. Alternatively, for example, the maximum value of the proximity effect-corrected dose of a proximity mesh region whose position overlaps the main chip region is set as the threshold value Dpth with reference to the proximity effect-corrected dose map.

In the modified corrected dose map creation step (S118), the limited corrected dose calculation unit 58 changes (overwrites) the value of the proximity effect-corrected dose of the proximity mesh region having a proximity effect-corrected dose larger than the threshold value Dpth to a limited corrected dose Dp′(x) that is more limited than the calculated proximity effect-corrected dose.

Then, the limited corrected dose calculation unit 58 creates a modified corrected dose map (second proximity effect-corrected dose map) in which the proximity effect-corrected dose for each proximity mesh region is defined and in which the proximity effect-corrected dose larger than the threshold value Dpth has been changed to the limited corrected dose Dp′(x).

However, if this continues, the incident dose becomes insufficient and accordingly, the line width of the written pattern decreases in the pixel 36 where the value of the proximity effect-corrected dose is limited. Therefore, the ghost dose is calculated as follows.

In the ghost dose calculation step (S120), the ghost dose calculation unit 60 calculates a ghost dose G(x) for ghost exposure for a proximity mesh (an example of a small region) that has a proximity effect-corrected dose greater than the threshold value Dpth as a result of the determination in the determination step (S116). The ghost dose G(x) is calculated for each region larger than the pixel 36, for example, for each proximity mesh region.

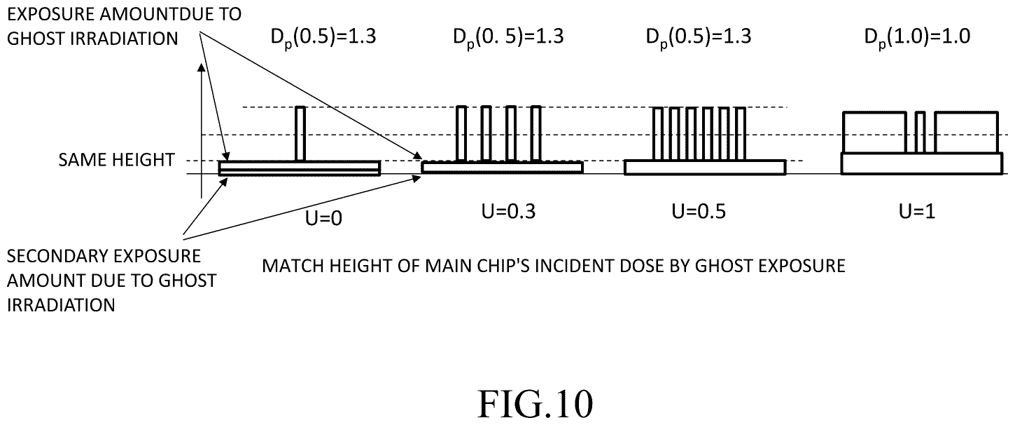

FIG. 10 is a diagram showing an example of the relationship between the proximity effect density and the dose in Embodiment 1. In the example of FIG. 10, the proximity effect-corrected dose Dp when the base exposure density of the beam (base dose) is normalized as 1 is shown as a dose. In addition, in the example of FIG. 10, an example of the dose required when the proximity effect density U is, for example, 0, 0.3, 0.5, and 1 in the development threshold model is shown. As described above, in the development threshold model for electron beam writing, half the dose is set to be the development threshold for resolving the resist on the surface of the target object 101. Therefore, by setting the proximity effect-corrected dose used in the main chip region, for example, the proximity effect-corrected dose Dp(U) when U=0.5, as a dose limit value Dpth and setting a back scattering dose Dp(U′) ηU′, which becomes a base portion at the dose limit value Dpth, to the same amount as the dose of a base portion at the proximity effect density U smaller than the proximity effect density U′ used at the dose limit value Dpth, the dose at the proximity effect density U (for example, U<0.5) which is smaller than the proximity effect density U′ (for example, U′=0.5) used at the dose limit value Dpth can be adjusted in the same manner as in the case of U′. Therefore, the shortage of the back scattering dose D(U)pηU of the base portion at the proximity effect density U (for example, U<0.5) smaller than the proximity effect density U′ used at the dose limit value Dpth is compensated for by the ghost dose G(x). The shortage of the back scattering dose can be defined by the following Equation (3) using the proximity effect density U′ used in the threshold value. In addition, in Equation (3), the back scattering dose Dp(U′) ηU′ at the threshold value Dpth is approximated by Dp(U′) ηU.

$$Δ D = Dp ( {U}^{′} ) η U - Dp ( U ) η U \qquad ( 3 )$$

Therefore, the ghost dose G(x) can be defined by the following Equation (4).

$$G ( x ) = ( Dp ( U ( x ) ) - Dp ( {U}^{′} ( x ) ) ) η U ( x ) / ( 1 + η ) \qquad ( 4 )$$

In addition, since irradiation with a ghost dose generates a secondary back scattering amount for the ghost dose, the dose is calculated taking this amount into consideration in Equation (4).

Therefore, for a proximity mesh region where the proximity effect-corrected dose Dp(x) is larger than the proximity effect-corrected dose Dp′(x) that is the threshold value Dpth, the ghost dose G(x) is taken into consideration, so that the proximity effect-corrected dose Dp(x) can be limited to the proximity effect-corrected dose Dp′(x) that is a threshold value while maintaining the pattern size.

In the dose map creation step (S130), for the pixel 36 having a proximity effect-corrected dose larger than the threshold value Dpth, the dose calculation unit 62 calculates an incident dose by adding the ghost dose G(x) to the dose ρ(x) Dp′(x) based on the limited corrected dose Dp′(x) that is more limited than the calculated proximity effect-corrected dose Dp(x). In addition, for the pixel 36 having a proximity effect-corrected dose Dp(x) that is not larger than the threshold value Dpth, an incident dose based on the calculated proximity effect-corrected dose Dp(x) is calculated without ghost exposure. An incident dose s(x) for a pixel without ghost exposure is defined by Equation (5-1) in which the proximity effect-corrected dose Dp(x) is multiplied by the pattern area density ρ(x) of the pixel 36. The incident dose s(x) for a pixel with ghost exposure is defined by Equation (5-2) in which the ghost dose g(x) is added to the value obtained by multiplying the proximity effect-corrected dose Dp(x) by the pattern area density ρ(x) of the pixel 36.

$$s = ρ ( x ) Dp ( x ) \qquad ( 5 - 1 )$$

$$s ( x ) = ρ ( x ) {Dp}^{′} + G ( x ) = ρ ( x ) {Dp}^{′} ( x ) + ( Dp ( U ) - Dp ( {U}^{′} ) ) ηU / ( 1 + η ) \qquad ( 5 - 2 )$$

In addition, the incident dose s(x) herein is defined as a relative value normalized with the base exposure density of the beam (base dose) being 1.

Then, the dose calculation unit 62 creates a dose map that defines the calculated incident dose s(x) for each pixel 36.

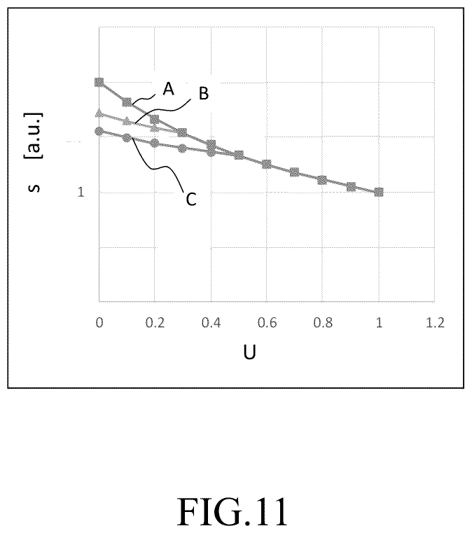

FIG. 11 is a diagram showing an example of the relationship between the dose and the proximity effect density in Embodiment 1. In FIG. 11, the vertical axis indicates a dose s [a.u.]. The horizontal axis indicates the proximity effect density U. In the example of FIG. 11, a case is shown in which the pattern area density p within a pixel is set to 1 (so-called solid pattern case). In the example of FIG. 11, a conventional incident dose s without ghost exposure (graph A), an incident dose s with ghost exposure when the proximity effect density at the threshold value Dpth is U=0.3 (graph B), and an incident dose s with ghost exposure when the proximity effect density at the threshold value Dpth is U=0.5 (graph C) are shown. As shown in FIG. 11, it can be seen that by performing ghost exposure, the maximum value of the incident dose s can be greatly reduced in the graph C compared to the graph A. As a result, the pattern writing accuracy in the main chip region can be maintained, and the writing time can be shortened while maintaining the pattern size in the peripheral chip region.

In the writing step (S140), first, the beam irradiation time calculation unit 64 calculates the beam irradiation time t for each pixel 36. The incident dose D(x) for actual irradiation can be calculated as a value obtained by multiplying the normalized incident dose s(x) by, for example, the base exposure density of the beam Dbase. In addition, the beam irradiation time t can be calculated by dividing D(x) by the current density J. Specifically, the beam irradiation time calculation unit 64 operates as follows. The beam irradiation time calculation unit 64 calculates the beam irradiation time t for each pixel 36 by dividing the value, which is obtained by multiplying the normalized incident dose s(x) by, for example, the base exposure density of the beam Dbase, by the current density J with reference to the dose map.

Then, the writing control unit 72 rearranges the obtained beam irradiation time data for each pixel 36 in a shot order and stores the result in the storage device 142. The transfer processing unit 74 transfers the beam irradiation time data to the deflection control circuit 130 in the shot order.

Then, under the control of the writing control unit 72, the writing mechanism 150 writes, for a plurality of pixels 36 to be irradiated with an electron beam that are obtained by dividing the striped region 32 (writing region) of the target object 101 in a mesh shape, the pixel 36 having a proximity effect-corrected dose larger than the dose limit value Dpth with an electron beam having the incident dose D(x) obtained by adding the ghost dose G(x) to a dose based on the limited corrected dose Dp′(x) that is more limited than the calculated proximity effect-corrected dose Dp(x). In addition, the pixel 36 having a proximity effect-corrected dose that is not larger than the threshold value Dpth is written with an electron beam having the incident dose D(x) based on the calculated proximity effect-corrected dose Dp(x) without ghost exposure.

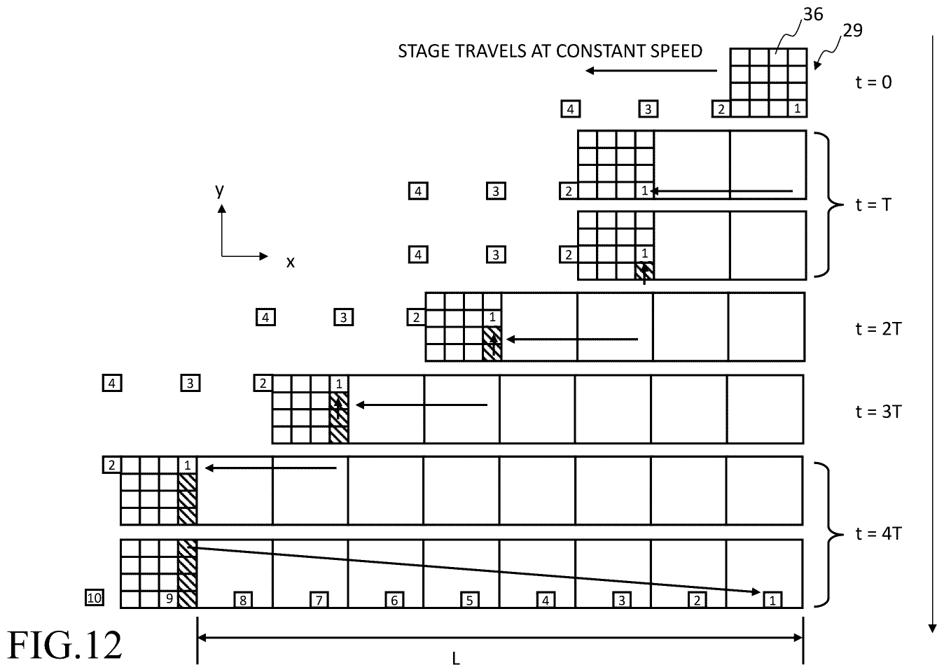

FIG. 12 is a diagram for explaining an example of a multi-beam writing operation in Embodiment 1. In the example of FIG. 12, a case is shown in which each sub-irradiation region 29 including one beam irradiation position of the multiple beams 20 and surrounded with the pitch between beams is written with four different beams. In addition, the example of FIG. 12 shows a writing operation in which the XY stage 105 moves continuously at a speed for movement by a distance L of eight beam pitches while writing a ¼ region (1/the number of beams used for irradiation) in each sub-irradiation region 29. In the example of FIG. 12, a case is shown in which each sub-irradiation region 29 is formed by, for example, 4×4 pixels. In the writing operation shown in the example of FIG. 12, for example, four different pixels 36 within the same sub-irradiation region 29 are written (exposed) by performing four shots of the multiple beams 20 with a shot cycle T while shifting the irradiation position (pixel 36) sequentially by the sub-deflector 209 during the movement of the XY stage 105 by the distance L of eight beam pitches. The shot cycle T is set to be longer than the exposure time corresponding to the maximum dose to be applied to each pixel. The irradiation region 34 is caused to follow the movement of the XY stage 105 by collectively deflecting all of the multiple beams 20 with the main deflector 208, so that the relative position of the irradiation region 34 with respect to the target object 101 does not shift due to the movement of the XY stage 105, while writing (exposing) the four pixels 36. In other words, tracking control is carried out. When one tracking cycle ends, the tracking is reset to return to the previous tracking start position. In addition, since the writing of the first pixel column from the right of each sub-irradiation region 29 has been completed, in the next tracking cycle after tracking reset, the sub-deflector 209 first performs deflection to match (shift) the writing position of the beam so as to write, for example, the second pixel column from the right that has not yet been written in each sub-irradiation region 29. By repeating this operation while writing the striped region 32, the position of the irradiation region 34 (34a to 34o) of the multiple beams 20 is sequentially moved as shown in the lower diagram of FIG. 4 to perform writing. In this manner, the writing mechanism 150 performs raster beam writing to irradiate each pixel 36 with a beam having a desired incident dose D(x). A desired pattern is written by combining pixels on which the desired incident dose D(x) has been incident.

As described above, according to Embodiment 1, in raster beam writing, the writing time can be shortened while maintaining the pattern size in the peripheral chip region without affecting the pattern writing accuracy in the main chip region.

### Embodiment 2

In Embodiment 1, a configuration has been described in which the dose increased by ghost exposure is not limited, but the invention is not limited thereto. In Embodiment 2, a configuration will be described in which, taking ghost exposure into consideration, a maximum dose is set for the dose of each pixel and any dose exceeding the maximum dose is limited. In Embodiment 2, the contents other than those specifically described below are the same as those in Embodiment 1.

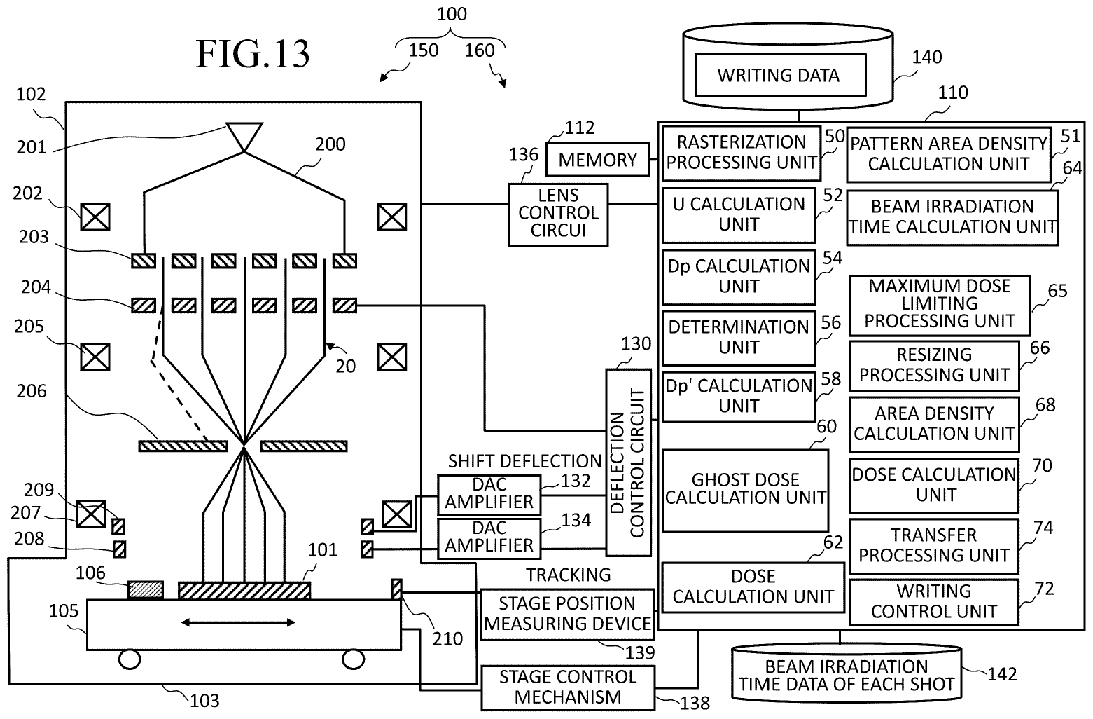

FIG. 13 is a conceptual diagram showing the configuration of a writing apparatus according to Embodiment 2. FIG. 13 is the same as FIG. 1 except that a maximum dose limiting processing unit 65, a resizing processing unit 66, an area density calculation unit 68, and a dose calculation unit 70 are further added in the control calculator 110.

Each “˜ unit”, such as the rasterization processing unit 50, the pattern area density calculation unit 51, the proximity effect density calculation unit 52, the proximity effect-corrected dose calculation unit 54, the determination unit 56, the limited corrected dose calculation unit 58, the ghost dose calculation unit 60, the dose calculation unit 62, the beam irradiation time calculation unit 64, the maximum dose limiting processing unit 65, the resizing processing unit 66, the area density calculation unit 68, the dose calculation unit 70, the writing control unit 72, and the transfer processing unit 74, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input to and output from the rasterization processing unit 50, the pattern area density calculation unit 51, the proximity effect density calculation unit 52, the proximity effect-corrected dose calculation unit 54, the determination unit 56, the limited corrected dose calculation unit 58, the ghost dose calculation unit 60, the dose calculation unit 62, the beam irradiation time calculation unit 64, the maximum dose limiting processing unit 65, the resizing processing unit 66, the area density calculation unit 68, the dose calculation unit 70, the writing control unit 72, and the transfer processing unit 74 and information being calculated are stored in the memory 112 each time.

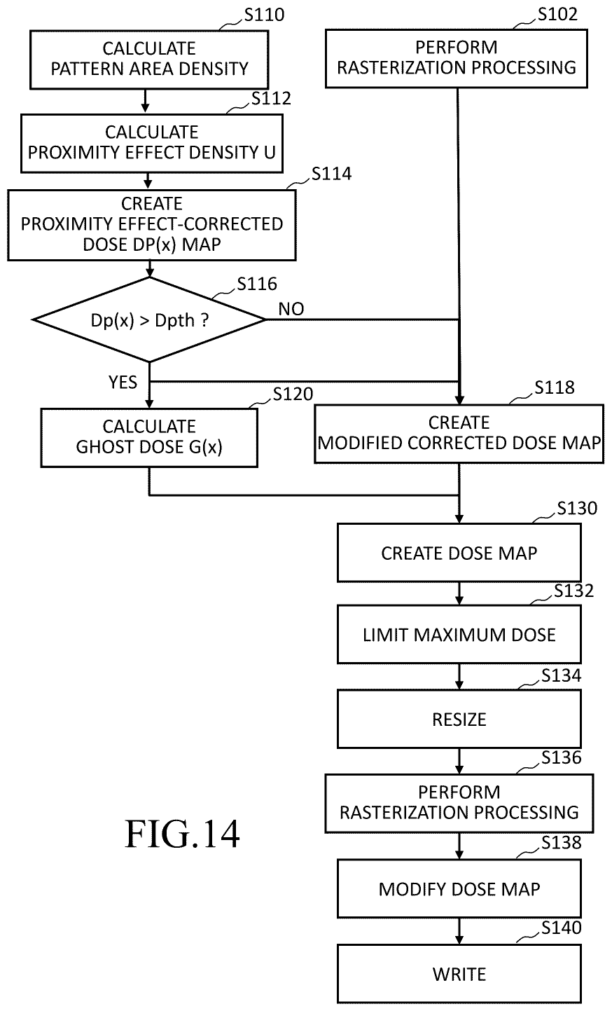

FIG. 14 is a flowchart showing an example of main steps of a writing method according to Embodiment 2. FIG. 14 is the same as FIG. 8 except that a maximum dose limiting step (S132), a resizing step (S134), a rasterization processing step (S136), and a dose map creation step (S138) are executed between the dose map creation step (S130) and the writing step (S140).

The contents of each step from the rasterization processing step (S102) to the dose map creation step (S130) are the same as those in Embodiment 1.

In the maximum dose limiting step (S132), the maximum dose limiting processing unit 65 limits the dose s(x) of the pixel 36 exceeding a maximum dose s₀, which is set in advance and is actually used in writing, to the maximum dose s₀. Here, for example, the maximum dose so normalized with the base exposure density of the beam Dbase being 1 is used. It is preferable to set the maximum dose s₀ to a value larger than the maximum value of the dose s(x) of a pixel in the main chip region. Since it is often difficult to set the maximum dose s(x) of a pixel in the main chip region in advance, it is preferable to set the maximum dose so to a value (Dp(U′=0.5)+α) larger than Dp(U′=0.5), for example. It is preferable to set α to a value of, for example, 5 to 20% of Dp(U′=0.5). For example, a is set to 10% of Dp(U′=0.5).

In the resizing step (S134), the resizing processing unit 66 resizes the figure pattern according to the insufficient dose ΔE due to being limited to the maximum dose so.

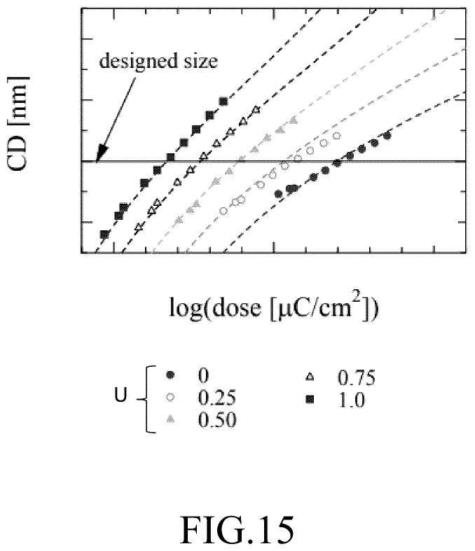

FIG. 15 is a diagram showing an example of the relationship between the pattern size and the dose in Embodiment 2. In FIG. 15, the vertical axis indicates a pattern size CD, and the horizontal axis indicates the dose. Such a relationship makes it possible to calculate a dose latitude DL (U). The dose latitude DL (U) indicates a CD change rate per unit dose for each proximity effect density U. The relationship between the pattern size CD and the dose is determined in advance by writing experiments or simulations.

The insufficient dose ΔE when the maximum dose is limited to so is defined by the following Equation (6).

$$Δ E = {s}_{0} - s ( x ) \qquad ( 6 )$$

The pattern size is reduced due to the insufficient dose ΔE, but a pattern resizing amount ΔCD required to compensate for this is defined by the following Equation (7) using the dose latitude DL (U).

$$Δ CD = ( - Δ E / s ( x ) ) DL ( U ) \qquad ( 7 )$$

Then, for each pixel limited to the maximum dose so, the size of the figure pattern within the pixel 36 is resized by ΔCD. Specifically, the line width is increased by ΔCD. As a result, even if the dose is insufficient, the pattern size after writing can be maintained in general.

In the rasterization processing step (S136), the area density calculation unit 68 calculates, for each pixel 36, a pattern area density p within the pixel. Since the area density of the pattern within a pixel changes due to resizing, this is calculated again. In addition, the target pixels for this calculation may be all pixels, or may be only pixels limited to the maximum dose so.

In the dose map creation step (S138), the dose calculation unit 70 calculates the incident dose s(x) using the recalculated pattern area density ρ. The incident dose s(x) for the pixel 36 limited to the maximum dose so is defined by Equation (8).

$$s ( x ) = ρ ( x ) {s}_{0} \qquad ( 8 )$$

The incident dose s(x) for the pixel 36 that is not limited to the maximum dose so is defined by Equation (5-1) or Equation (5-2).

Then, the dose calculation unit 70 creates a dose map that defines the newly calculated incident dose s(x) for each pixel 36.

The contents of the writing step (S140) are the same as those in Embodiment 1.

As described above, it is also preferable to set the maximum dose in advance and limit the maximum value of the incident dose.

According to Embodiment 2, the writing time can be further shortened compared to Embodiment 1.

Up to now, the embodiments have been described with reference to specific examples. However, the invention is not limited to these specific examples. In the above examples, the case where only the proximity effect is corrected has been described, but the invention is not limited thereto. A corrected dose for correcting dimensional errors due to other causes may be added. For example, there may be fogging effects, loading effects, and/or effects specific to figure pattern(s).

In addition, each of the above embodiments, the writing region 30 is divided into a plurality of striped regions 32 (processing regions) as described above. Then, each striped region 32 can be written by a single continuous movement of the XY stage 105 on which the target object 101 is placed in, for example, the x direction (predetermined direction), as described above. In other words, all the pixels 36 in the target striped region 32 can be written by a single continuous movement of the XY stage 105 in, for example, the x direction (predetermined direction). In addition, in other words, the writing region 30 includes a plurality of striped regions 32 that are virtually divided into striped regions 32 that can be written by a single continuous movement of the XY stage 105, on which the target object 101 is placed, in the x direction (predetermined direction).

Here, in at least one of the plurality of striped regions 32, the pixel 36 that is written with an electron beam having an incident dose obtained by adding a ghost dose to a dose based on the limited corrected dose and the pixel 36 that is written with an electron beam having an incident dose based on the calculated proximity effect-corrected dose without ghost exposure may be mixed. In such a case, in the writing process of at least one of the plurality of striped regions 32, depending on a pixel to be written, switching is performed between writing with an electron beam having an incident dose obtained by adding a ghost dose to a dose based on the limited corrected dose and writing with an electron beam having an incident dose based on the calculated proximity effect-corrected dose without ghost exposure.

In addition, the description of parts that are not directly required for the description of the present invention, such as the apparatus configuration or the control method, is omitted. However, the required apparatus configuration, control method, and the like can be appropriately selected and used. For example, although the description of the control unit configuration for controlling the writing apparatus 100 is omitted, it is needless to say that the required control unit configuration can be appropriately selected and used.

In addition, all raster beam writing methods and raster beam writing apparatuses that include the elements of the invention and that can be appropriately redesigned by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A raster beam writing method, comprising:
calculating a normalized proximity effect-corrected dose for correcting a proximity effect in a case of writing a target object with a charged particle beam;
determining, for each of a plurality of small regions obtained by dividing a writing region of the target object in a mesh shape, whether or not a proximity effect-corrected dose of a small region is larger than a threshold value;
calculating a ghost dose for ghost exposure for a small region having a proximity effect-corrected dose larger than the threshold value as a result of the determination; and
for a plurality of irradiation unit regions to be irradiated with a charged particle beam obtained by dividing the writing region of the target object in a mesh shape, writing an irradiation unit region having a proximity effect-corrected dose larger than the threshold value with a charged particle beam having an incident dose obtained by adding the ghost dose to a dose based on a limited corrected dose more limited than a calculated proximity effect-corrected dose, and writing an irradiation unit region having a proximity effect-corrected dose not larger than the threshold value with a charged particle beam having an incident dose based on the calculated proximity effect-corrected dose without ghost exposure.

2. The method according to claim 1,
wherein the writing region includes a plurality of processing regions divided using a processing region written by a single continuous movement of a stage in a predetermined direction, the target object being placed on the stage, and
in a writing process of at least one of the plurality of processing regions, switching is performed between writing with a charged particle beam having an incident dose obtained by adding the ghost dose to a dose based on the limited corrected dose and writing with a charged particle beam having an incident dose based on the calculated proximity effect-corrected dose without the ghost exposure.

3. The method according to claim 1,
wherein the writing region of the target object has a main writing region located in a central portion of the target object and a sub-writing region located around the main writing region, and
a value equal to or greater than a proximity effect-corrected dose used in the main writing region is used as the threshold value.

4. The method according to claim 1,
wherein the ghost dose is calculated for each region having a size larger than an irradiation unit region to be irradiated with the charged particle beam.

5. The method according to claim 1, further comprising:
creating a proximity effect-corrected dose map defining a proximity effect-corrected dose for each small region of the plurality of small regions, the proximity effect-corrected dose larger than the threshold value being changed to the limited corrected dose in the proximity effect-corrected dose map.

6. The method according to claim 1, further comprising:
limiting an incident dose of an irradiation unit region exceeding a maximum dose set in advance and actually used in writing to the maximum dose; and
resizing a figure pattern according to an insufficient dose due to being limited to the maximum dose.

7. A raster beam writing apparatus, comprising:
a proximity effect-corrected dose calculation circuit configured to calculate a normalized proximity effect-corrected dose for correcting a proximity effect in a case of writing a target object with a charged particle beam;
a determination circuit configured to determine, for each of a plurality of small regions obtained by dividing a writing region of the target object in a mesh shape, whether or not a proximity effect-corrected dose of a small region is larger than a threshold value;
a ghost dose calculation circuit configured to calculate a ghost dose for ghost exposure for a small region having a proximity effect-corrected dose larger than the threshold value as a result of the determination; and
a writing mechanism configured, for a plurality of irradiation unit regions to be irradiated with a charged particle beam obtained by dividing the writing region of the target object in a mesh shape, to write an irradiation unit region having a proximity effect-corrected dose larger than the threshold value with a charged particle beam having an incident dose obtained by adding the ghost dose to a dose based on a limited corrected dose more limited than the calculated proximity effect-corrected dose and write an irradiation unit region having a proximity effect-corrected dose not larger than the threshold value with a charged particle beam having an incident dose based on the calculated proximity effect-corrected dose without ghost exposure.
